(19) United States
(12) Patent Application Publication
(10) Pub. No.: US 2011/0095399 A1
(43) Pub. Date: Apr. 28, 2011

(54) Method For Manufacturing Semiconductor Chips From A Wafer

(76) Inventors: Richard Spitz, Reutllingen (DE); Alfred Goerlach, Kusterdingen (DE); Friderike Hahn, Reutlingen (DE)

(21) Appl. No.: 11/794,454

(22) PCT Filed: Nov. 7, 2005
(86) PCT No.: PCT/EP2005/055790

§ 371 Date: Jan. 13, 2009

(30) Foreign Application Priority Data
Dec. 29, 2004 (DE) 102004063180.8

(51) Int. Cl. H01L 21/782; H01L 29/866

(52) U.S. Cl. 257/603; 438/462; 257/E29.335; 257/E21.7

(57) ABSTRACT

A method is for manufacturing semiconductor chips from a wafer which includes a plurality of semiconductor chips. Defects in the crystal structure of the chips may be substantially reduced by producing rupture joints in the surface of the wafer after the wafer has been produced, and by breaking the wafer along the rupture joints to separate the semiconductor chips.

### FIELD OF THE INVENTION

The present invention relates to a method for manufacturing semiconductor chips from a wafer, as well as a semiconductor device manufactured using the method.

### BACKGROUND INFORMATION

Semiconductor devices such as diodes, transistors, or thyristors customarily include a semiconductor chip enclosed in a package. The semiconductor chips are usually manufactured from a wafer which customarily includes a very large number of identical semiconductor chips. After the wafer is produced, usually following a final metal plating step, the chips are separated from the wafer. The chips are usually separated using a diamond saw. Although this sawing process is relatively easy to implement, it has the disadvantage that crystal defects are produced in the cut surfaces along the entire edge of the chip, and these defects extend into the chip to a depth of up to some 10 micrometers. These crystal defects are critical, particularly in the case of devices which have a p-n junction on the edge of the chip. In this case, the p-n junction ends in the area of the defective crystal zone and is defective at this point. In the case of Z diodes, substantially higher reverse currents, for example, are observable as a result.

A conventional method for removing the defective crystal regions, for example, includes etching the side edges of the chip and thereby also reduces the reverse currents. However, this requires an additional complex and costly process step.

### SUMMARY

Example embodiments of the present invention provide a method for separating semiconductor chips, in particular Z diodes, from a wafer which produces fewer crystal defects in the region of the p-n junction of the chip.

According to example embodiments of the present invention, after the wafer is produced (usually following a final metal plating process), rupture joints are created in the wafer surface, e.g., in the form of linear indentations, and the wafer is broken along the rupture joints to separate the semiconductor chips. Breaking the wafer provides that fewer crystal defects occur on the side surfaces of the chips, compared to sawing. Particularly in the case of Z, or Zener, diodes, this provides for the reverse current to be reduced.

Furthermore, it is not absolutely necessary to post-process the side surfaces of the chips after separation to remove crystal defects, which provides for an additional process step to be eliminated. It is generally also possible to overetch the chip edges after breaking to even further reduce the reverse currents in certain instances. However, a much smaller amount of etched material may be selected to be removed, e.g., less than 10 μm, since the defective crystal region no longer penetrates to a great depth (flash etching). All etching methods used in semiconductor engineering may be used as the etching method. The etching process may also be carried out at a later point in time, e.g., following solder assembly.

The method hereof for separating semiconductor chips may be used, in particular, for devices whose semiconductor chips have a p-n junction extending to the side edge of the chip and, in particular, a p-n junction of a type in which the difference in charge density is smaller in the edge region of the chip than in the middle of the chip. The space-charge zone is thereby extended farther on the edge than in the middle of the chip, so that the electrical field strength in the edge region is also reduced. This arrangement of the p-n junction provides that the device is relatively insensitive to crystal defects on the side edge of the chip. The side break edges of the semiconductor chips therefore no longer have to be post-processed, e.g., by etching, to remove the crystal defects.

Suitable devices in which the p-n junction ends in the edge region of the chip include diodes, Z diodes, Zener diodes, transistors, thyristors, etc. Suitable devices which include a p-n junction having a reduced edge field strength are, in particular, ZR diodes.

The rupture joints may be produced by sawing, e.g., using a diamond saw. Alternatively, the rupture joints may also be produced, for example, using a laser or photolithographic methods followed by wet or dry etching.

In producing the rupture joints in the wafer surface, care should be taken to provide that the depth of the rupture joints is less than the depth of the p-n junction in the edge region of the chip. In other words, the rupture joint should not extend beyond the p-n junction. This is particularly true when producing rupture joints by sawing the wafer surface, since the crystal structure in the region of the p-n junction would otherwise also be damaged.

The rupture joints may be produced either on the front, the back, or on the front and back of the wafer.

The orientation of the rupture joints in relation to the crystal structure of the wafer may be selected such that the rupture joins extend parallel to crystal surfaces which are easily broken. Another orientation may also be selected, although this is less favorable.

In the case of a (100)-oriented silicon wafer, the rupture joints may extend parallel or vertical to a (100) orientation flat, which produces rectangular chips. If a (111)-oriented silicon wafer is used, hexagonal semiconductor chips may also be manufactured. In this case, the rupture joints extend at 30° and 90° angles in relation to a (110)-identification flat. In this case, the break edges of the individual chips, in turn, extend in the direction of easy-to-break (111) crystal surfaces.

According to an example embodiment of the present invention, the wafer is mounted on a film, e.g., a self-adhesive film, prior to separating the chips, and the wafer is broken in this state. After breaking, the film may be stretched and the individual chips picked directly off the film for further processes, for example for soldering or packaging.

The wafer in this case may be broken in the direction of the film. This prevents the chips from rubbing against one another during breaking and becoming damaged.

Example embodiments of the present invention are explained in greater detail below with reference to the attached drawings.

### BRIEF DESCRIPTION OF THE DRAWINGS

FIG. 1 shows a side view of a conventional chip of a Z diode having a reduced edge field strength.

FIG. 2 shows a side view of the chip of a Z diode having a reduced edge field strength according to an example embodiment of the present invention.

FIGS. 3a, 3b show different wafers having different crystal orientations.

FIGS. 4a-4c show different example embodiments of diamond saws for sawing the wafer surface.

### DETAILED DESCRIPTION

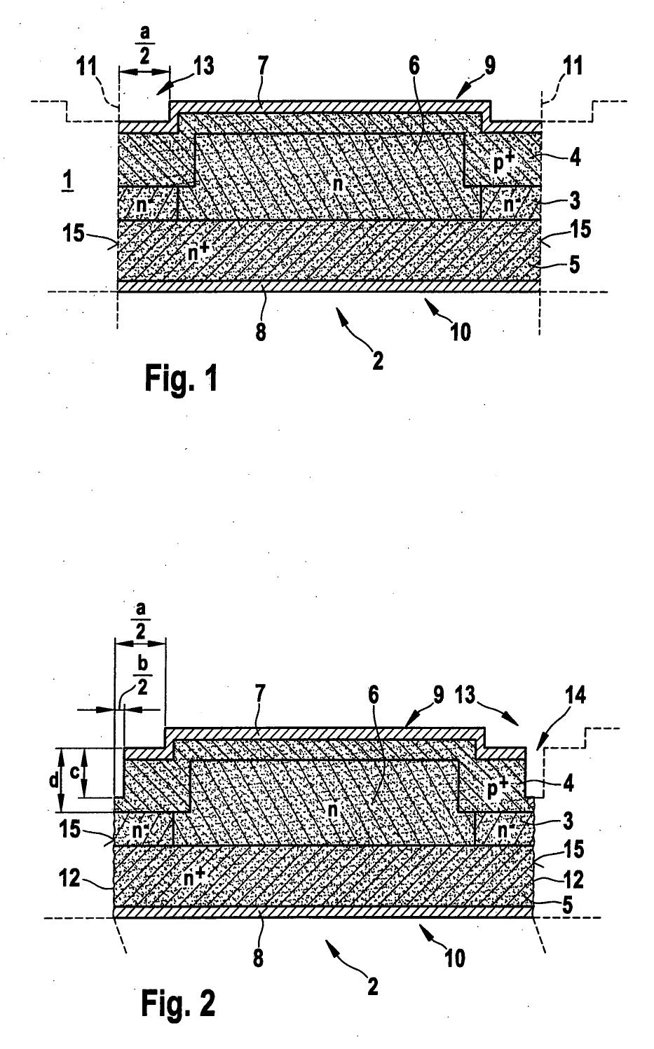

FIG. 1 shows a conventional semiconductor chip 2 of a Z diode having a reduced edge field strength, which is also referred to as a ZR diode. Diode chip 2 is made from a silicon substrate, which has, for example, an n-doped region of approximately 8×1015 cm-3. Viewed from front 9 to back 10, chip 2 has a p+-doped layer 4, an underlying n-doped substrate layer 6 which is surrounded at the side by p+-type layer 4, and an underlying lightly n−-doped layer 3 as well as a heavily n+-doped layer 5 situated on back 10 of the chip. Metal plating layers 7 and 8 are also provided on front 9 and back 10, respectively.

The ZR diode is characterized in that breakdown during operation in the reverse direction occurs only in the middle of the chip and not in the edge region of diode chip 2. This effect is based on the fact that the Z diode has different p-n junctions in the middle and on edge 15 of diode chip 2. In the middle region of the diode chip, the p-n junction is formed by layers 4-6 and in the edge region by layers 4-3, the difference in charge density being much higher in the middle region than in the edge region. As a result, the breakdown voltage of middle p-n junction 4-6 is also lower than the breakdown voltage of p-n junction 4-3. This provides that avalanche breakdown occurs only in the middle of the chip and not on the edge. During operation in the reverse direction, the space charge zone on the edge of chip 2 also expands more than in the middle of the chip, so that the electrical field strength is lower in the edge region than in the middle. The Z diode is therefore also referred to as a ZR diode (having a reduced edge field strength).

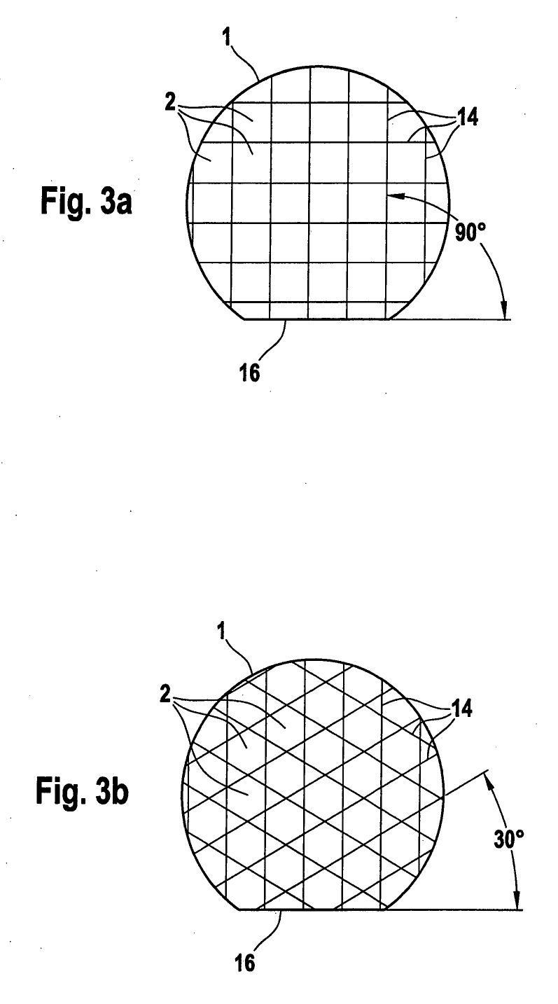

Diode chips 2 are manufactured from a wafer 1, for example a silicon wafer, as shown in FIGS. 3a and 3b. Conventionally, after wafer 1 is produced, the wafer disks are sawn along edges 15 of chips 2 to separate the chips. In FIG. 1, the cut edges are identified by reference numeral 11. However, sawing wafer 1 has the disadvantage that crystal defects which may impair the function of the device are produced in the cut surfaces along the entire edge of the chip.

FIG. 2 shows a diode chip 2 of a Z diode which is identical to the one in FIG. 1 with regard to the doping profile. In contrast to diode chip 2 according to FIG. 1, this diode chip, however, has rupture joints 14 (shown as an indentation) along which wafer 1 is broken. The side break edges are identified by reference numeral 12. Breaking wafer 1 has the advantage that many fewer crystal defects are produced in the region of p-n junction 4-3, compared to sawing, which means that the reverse current of the Z diode may also be reduced.

Side edges 15 are drawn in simplified form at right angles to front 9 and back 10, respectively. This is not correct for all crystal orientations, since the breaking crystal surfaces do not necessarily extend perpendicularly, but often also extend slightly diagonally. This must be taken into account when producing rupture joints 14 on both front 9 and back 10.

The representation of a ZR diode in this case is selected only by way of example. Alternatively, example embodiments of the present invention are also applicable to other devices which have a p-n junction extending to side edge 15 of the semiconductor chip, for example other diodes, transistors, thyristors, etc., in particular such devices in which the current flow is less in the edge region than in the middle of the chip.

In manufacturing the chips, rupture joints 14 are produced in the surface of the wafer in a first process step, and the wafer is then broken along these rupture joints 14 to separate chips 2. Rupture joints 14 in this case are represented as linear indentations, but they may also have a different shape or be formed, for example, by perforations.

Rupture joints 14 may be produced using a diamond saw, but they may also be created by laser cutting or photolithographic methods, followed by etching. In particular when sawing rupture joints 14, care should be taken to provide that depth c of the saw incision is less than depth d of p-n junction 4-3 in the edge region of semiconductor chip 2, since the crystal structure would otherwise, in turn, become damaged in the region of p-n junction 4-3.

Width b of the saw blade may be, for example, between 100 μm and 300 μm and sawing depth c may be, for example, between 2 μm and 60 μm. After rupture joints 14 have been produced, chips 2 are separated by breaking wafer 1. This is done, for example, by applying a force over a wide area of the surface of wafer 1, using a roller.

The rupture joints are shown only on front 9 of the chip, but they may also be provided on back 10 or on both sides.

Rupture joints 14 may extend parallel to crystal surfaces which are easily broken. In the case of a silicon wafer, such surfaces are, in particular, the (111) planes.

FIGS. 3a and 3b show two silicon wafers 1 having different crystal orientations, wafer 1 in FIG. 3a having a (100) orientation and wafer 1 in FIG. 3b having a (111) orientation. In FIG. 3a, linear saw incisions 14 run vertically and parallel to a (110) orientation flat 16, which results in rectangular chips 2. In FIG. 3b, saw incisions 14 extend at a 30° angle as well as vertically to (110) orientation flat 16. This results in hexagonal chips 2 having easy-to-break (111) crystal surfaces.

In general, it is not absolutely necessary to always arrange the rupture joints parallel to the easy-to-split (111) crystal surfaces. For example, (111)-oriented wafer 1 in FIG. 3b may also be divided into squares, as shown in FIG. 3a. In this case, the harder-to-break (110) edges parallel to orientation flat 16 may be broken first, followed by the (111) edges positioned perpendicularly thereto.

Saw incisions 14 may be produced, for example, using a diamond saw which includes, for example, diamond fragments embedded in nickel. However, any specially shaped diamond saw blades may be used which are pointed or have another shape which deviates from the conventional rectangular shape.

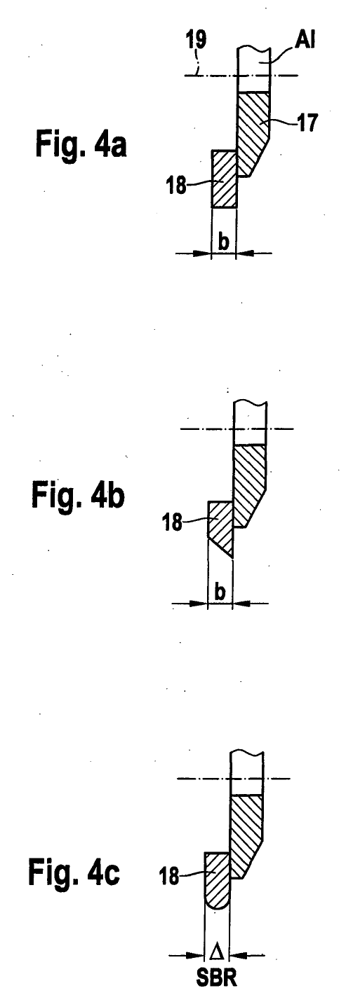

FIGS. 4a through 4c show different example embodiments of diamond saw blades having a mount 17 on which a cutting surface 18 is provided. The saw blade has a rotationally symmetrical arrangement and rotates around a rotation axis 19.

FIG. 4a shows a saw blade having a rectangular diamond cutting surface. The width of the cutting surface is identified by b. FIG. 4b shows a diamond saw blade having an outwardly tapered cutting surface 18, and FIG. 4c shows a diamond saw blade having an outwardly convex cutting surface. Cutting surfaces 18 according to FIGS. 4b and 4c may provide that they produce fewer crystal defects, compared to the example embodiment according to FIG. 4a.

### LIST OF REFERENCE CHARACTERS

1 Wafer
2 Semiconductor chip
3 Lightly doped n—type region
4 Heavily doped p+-type region
5 Heavily doped n+-type region
6 n-type region
7 Metal plating layer
8 Metal plating layer
9 Front
10 Back
11 Cut edge
12 Break edge
13 Trench
14 Rupture joint
15 Side surfaces
16 Orientation flat
17 Mount
18 Diamond cutting surface
19 Rotation axis
a Trench width
b Width of rupture joint 14
c Depth of rupture joint
d Depth of p-n junction 4-3

1-12. (canceled)

13. A method for manufacturing semiconductor chips from a wafer that includes a plurality of semiconductor chips, comprising:
producing rupture joints in a surface of the wafer; and
breaking the wafer along the rupture joints to separate the semiconductor chips.

14. The method according to claim 13, wherein the chip includes a ZR diode chip.

15. The method according to claim 13, wherein the rupture joints include as linear indentations.

16. The method according to claim 13, wherein, after the wafer is broken, side break edges of the semiconductor chips require one of (a) no further and (b) minimal further post-processing to remove crystal defects.

17. The method according to claim 13, wherein the semiconductor chips have a p-n junction that extends to a side edge of the semiconductor chip.

18. The method according to claim 13, wherein a depth of the rupture joints is less than a depth of a p-n junction situated in a side edge region of the semiconductor chips.

19. The method according to claim 13, wherein the rupture joints are produced by sawing into the wafer surface.

20. The method according to claim 13, wherein the rupture joints are produced in a front of the wafer.

21. The method according to claim 13, wherein the rupture joints are produced in a front and a back of the wafer.

22. The method according to claim 13, wherein an orientation of the rupture joints in relation to a crystal structure of the wafer is selected such that the rupture joints extend parallel to crystal surfaces that are easily broken.

23. The method according to claim 13, further comprising gluing the wafer provided with the rupture joints onto a film before the chips are separated.

24. A semiconductor device, comprising:
a semiconductor chip having a p-n junction extending to a side edge of the chip, the semiconductor chip manufactured from a wafer, the semiconductor chip having side break surfaces that require one of (a) no and (b) only minimal post-processing to remove crystal defects.

25. The semiconductor device according to claim 24, wherein the semiconductor device is arranged as a Z diode.

26. The semiconductor device according to claim 24, wherein the semiconductor chip includes an indication of a wafer rupture joint on the side edge.
